(19) United States
(12) Patent Application Publication
(10) Pub. No.: US 2026/0068716 A1
(43) Pub. Date: Mar. 5, 2026

(54) SEMICONDUCTOR PACKAGE

(71) Applicant: SAMSUNG ELECTRONICS CO., LTD., Suwon-si (KR)

(72) Inventor: Kuwon Lee, Suwon-si (KR)

(73) Assignee: SAMSUNG ELECTRONICS CO., LTD., Suwon-si (KR)

(21) Appl. No.: 19/177,084

(22) Filed: Apr. 11, 2025

(30) Foreign Application Priority Data
Sep. 2, 2024 (KR) 10-2024-0118806

(51) Int. Cl. H01L 23/498; H01L 23/00; H01L 23/31; H01L 23/538; H01L 25/03

(52) U.S. Cl. CPC H01L 23/49838

(57) ABSTRACT

A semiconductor package may be provided and include: a first wiring structure including a first wiring and a first wiring insulating layer surrounding the first wiring; a first semiconductor chip on the first wiring structure; a conductive pillar on the first wiring structure and spaced apart from the first semiconductor chip in a horizontal direction; a molding member covering the first semiconductor chip and the conductive pillar; and a second wiring structure on the molding member, wherein the second wiring structure includes a second wiring and a second wiring insulating layer surrounding the second wiring, wherein the conductive pillar includes a lower portion, a middle portion, and an upper portion, and wherein the upper portion of the conductive pillar includes a dome shape.

### CROSS-REFERENCE TO RELATED APPLICATION

This application is based on and claims priority under 35 U.S.C. § 119 to Korean Patent Application No. 10-2024-0118806, filed on Sep. 2, 2024, in the Korean Intellectual Property Office, the disclosure of which is incorporated by reference herein in its entirety.

### BACKGROUND

### 1. Field

Embodiments of the present disclosure relate to a semiconductor package, and more particularly, to a semiconductor package including conductive pillars.

### 2. Brief Description of Background Art

Recently, in the electronic products market, demand for portable devices is rapidly increasing. As a result, there is a continuous demand for smaller and lighter electronic components mounted on these electronic products. To make the electronic components smaller and lighter, semiconductor packages mounted thereon are required to process high amounts of data while becoming smaller in volume. As semiconductor packages become smaller and lighter, cracks may be formed inside the semiconductor packages.

### SUMMARY

According to embodiments of the present disclosure, a semiconductor package may be provided.

According to embodiments of the present disclosure, a semiconductor package may be provided and include: a first wiring structure including a first wiring and a first wiring insulating layer surrounding the first wiring; a first semiconductor chip on the first wiring structure; a conductive pillar on the first wiring structure and spaced apart from the first semiconductor chip in a horizontal direction; a molding member covering the first semiconductor chip and the conductive pillar; and a second wiring structure on the molding member, wherein the second wiring structure includes a second wiring and a second wiring insulating layer surrounding the second wiring, wherein the conductive pillar includes a lower portion, a middle portion, and an upper portion, and wherein the upper portion of the conductive pillar includes a dome shape.

According to embodiments of the present disclosure, a semiconductor package may be provided and include: a first wiring structure including a first wiring and a first wiring insulating layer surrounding the first wiring; a first semiconductor chip on the first wiring structure; a conductive pillar on the first wiring structure and spaced apart from the first semiconductor chip in a horizontal direction; a molding member covering the first semiconductor chip and the conductive pillar; and a second wiring structure on the molding member, wherein the second wiring structure includes a second wiring and a second wiring insulating layer surrounding the second wiring, wherein the second wiring includes a wiring line and a plurality of wiring vias, wherein the conductive pillar includes a lower portion, a middle portion, and an upper portion, wherein the lower portion of the conductive pillar is a first portion of the conductive pillar that has a cross-sectional area along a horizontal plane that is equal to a cross-sectional area of a lower surface of the conductive pillar along the horizontal plane, wherein the middle portion of the conductive pillar is a second portion of the conductive pillar that has a cross-sectional area along the horizontal plane that increases as a vertical level of the middle portion increases, wherein the upper portion of the conductive pillar is a third portion of the conductive pillar that has a vertical level that is greater than a vertical level of an upper surface of the molding member, wherein the upper portion of the conductive pillar includes a dome shape, and wherein the upper portion of the conductive pillar is in contact with the plurality of wiring vias.

According to embodiments of the present disclosure, a semiconductor package may be provided and include: a first wiring structure including a first wiring and a first wiring insulating layer surrounding the first wiring; a first semiconductor chip on the first wiring structure and connected to the first wiring structure by chip connection bumps; an underfill material layer between the first semiconductor chip and the first wiring structure and surrounding the chip connection bumps; a conductive pillar on the first wiring structure and spaced apart from the first semiconductor chip in a horizontal direction; a molding member covering the first semiconductor chip and the conductive pillar; a second wiring structure on the molding member, wherein the second wiring structure includes second wiring and a second wiring insulating layer surrounding the second wiring, wherein the second wiring includes a wiring line and a plurality of wiring vias; and a second semiconductor chip on the second wiring structure; wherein the conductive pillar includes a lower portion, a middle portion, and an upper portion, wherein the lower portion of the conductive pillar is a first portion of the conductive pillar that has a cross-sectional area along a horizontal plane that is equal to a cross-sectional area of a lower surface of the conductive pillar along the horizontal plane, wherein the middle portion of the conductive pillar is a second portion of the conductive pillar that has a cross-sectional area along the horizontal plane that increases as a vertical level of the middle portion increases, and at least a part of the middle portion of the conductive pillar does not overlap with the lower portion of the conductive pillar in a vertical direction, wherein the upper portion of the conductive pillar is a third portion of the conductive pillar that has a vertical level that is greater than a vertical level of an upper surface of the molding member, wherein the upper portion of the conductive pillar includes a dome shape, wherein the upper portion of the conductive pillar is in contact with the plurality of wiring vias, and wherein the part of the middle portion of the conductive pillar, that does not overlap with the lower portion of the conductive pillar in the vertical direction, and the upper portion of the conductive pillar are formed through electroless plating.

In addition, embodiments of the present disclosure are not limited to the example embodiments mentioned above and other embodiments of the present disclosure may be clearly understood by those skilled in the art from the description below.

### BRIEF DESCRIPTION OF DRAWINGS

Embodiments will be more clearly understood from the following detailed description taken in conjunction with the accompanying drawings in which:

FIG. 1 is a cross-sectional view of a semiconductor package according to an embodiment;

FIG. 2 is an enlarged view of a portion AA in FIG. 1;

FIG. 3 is a cross-sectional view of a semiconductor package according to an embodiment;

FIG. 4 is an enlarged view of a portion AA1 in FIG. 3;

FIG. 5 is a cross-sectional view of a semiconductor package according to an embodiment;

FIG. 6 is an enlarged view of a portion AA2 in FIG. 5;

FIG. 7 is a cross-sectional view of a semiconductor package according to an embodiment;

FIG. 8 is an enlarged view of a portion AA3 in FIG. 7;

FIG. 9 is a cross-sectional view of a semiconductor package according to an embodiment; and

FIGS. 10 to 15 are cross-sectional views illustrating a method of manufacturing a semiconductor package according to an embodiment.

### DETAILED DESCRIPTION

Hereinafter, non-limiting example embodiments are described in detail with reference to the accompanying drawing. The same reference numerals are used for the same components in the drawings and duplicate descriptions thereof may be omitted.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

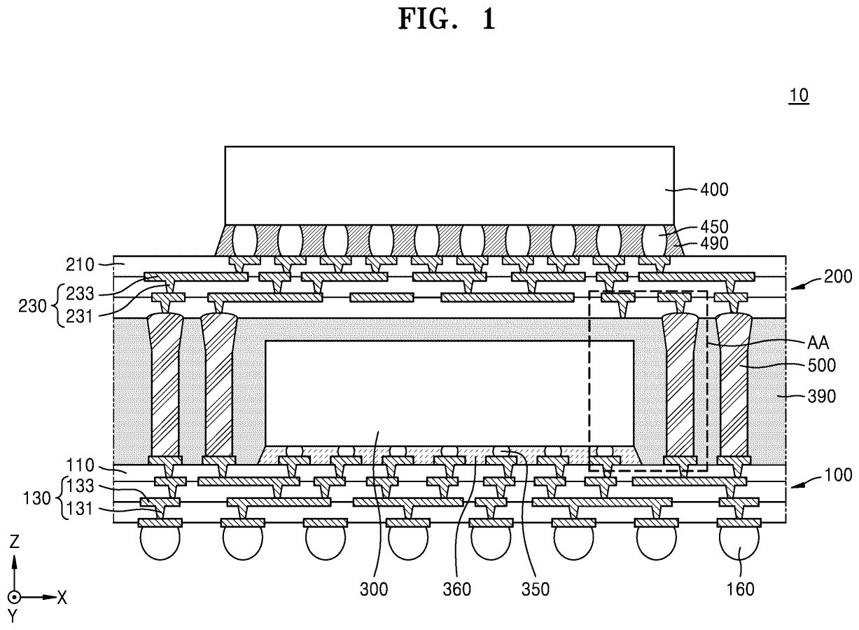

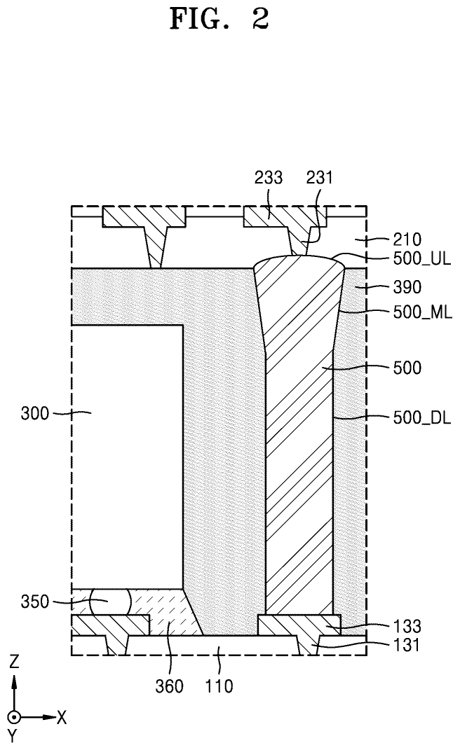

FIG. 1 is a cross-sectional view of a semiconductor package according to an embodiment. FIG. 2 is an enlarged view of a portion AA in FIG. 1.

Referring to FIGS. 1 and 2, a semiconductor package 10, according to embodiments of the present disclosure, may include a first wiring structure 100, a first semiconductor chip 300, a second wiring structure 200, a conductive pillar 500, a molding member 390, and a second semiconductor chip 400.

The first wiring structure 100 may include an upper surface and a lower surface, which are opposite to each other, wherein at least one of the upper surface and the lower surface thereof may be flat. The first wiring structure 100 may be arranged below the first semiconductor chip 300 and may electrically connect the first semiconductor chip 300 to external connection bumps 160. The first wiring structure 100 may include a first wiring insulating layer 110 and first wiring 130.

The first wiring insulating layer 110 may be provided as a plurality of insulating layers (e.g., a plurality of first wiring insulating layers 110) stacked in one direction, and the first wiring 130 may include a plurality of patterns formed in the plurality of stacked insulating layers.

In the drawings, the direction in which the plurality of insulating layers are stacked may be understood as a Z-axis direction. An X-axis direction and a Y-axis direction may be understood as directions perpendicular to each other in a plane having the Z-axis direction as a normal vector. In other words, the X-axis direction and the Y-axis direction may represent directions parallel to the upper surface or the lower surface of the first wiring structure 100. The X-axis direction and Y-axis direction may be perpendicular to each other. In addition, in the drawings, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

The first wiring 130 may be electrically connected to the conductive pillar 500 and the first semiconductor chip 300. The first wiring 130 may include a first wiring via 131 and a first wiring line 133. The first wiring line 133 may extend in the first horizontal direction X within the first wiring insulating layer 110. According to some embodiments, the first wiring line 133 may be provided as a plurality of first wiring lines in the plurality of first wiring insulating layers 110 stacked in the vertical direction Z, respectively. The first wiring via 131 may extend in the vertical direction Z and may pass through the first wiring insulating layer 110 in the vertical direction Z. The first wiring via 131 may electrically connect the first wiring lines 133, formed in each of the different ones of the first wiring insulating layers 110, to each other.

In some embodiments, the first wiring via 131 may have a tapered shape in which the horizontal width of the first wiring via 131 increases from a bottom to a top of the first wiring via 131. For example, the horizontal width of the first wiring via 131 increases as the distance between the first wiring via 131 and the first semiconductor chip 300 decreases. In some embodiments, the first wiring via 131 may have a tapered shape in which the horizontal width of the first wiring via 131 increases as a level of the first wiring via 131 in the vertical direction Z decreases.

In some embodiments, the first wiring structure 100 may include a rewiring structure that is manufactured through a rewiring process. The first wiring insulating layer 110 may include, for example, photo imageable dielectric (PID), or photosensitive polyimide (PSPI). The first wiring 130 may include, for example, metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), or an alloy thereof. However, embodiments of the present disclosure are not limited thereto. In some embodiments, the first wiring 130 may be formed by stacking metal or an alloy thereof on a seed layer, including Cu, Ti, titanium nitride (TiN), or titanium tungsten (TiW). According to some embodiments, the first wiring line 133 may be integrated with the first wiring via 131 to form one body.

As described above, when the first wiring structure 100 includes a rewiring structure manufactured through a rewiring process, the first wiring 130 may be understood as rewiring patterns and the first wiring insulating layer 110 may be understood as a rewiring insulating layer.

In some embodiments, the first wiring structure 100 may include a printed circuit board (PCB). The first wiring insulating layer 110 may include at least one material selected from among phenolic resin, epoxy resin, and polyimide. The first wiring insulating layer 110 may include at least one material selected from among, for example, flame retardant 4 (FR-4), tetrafunctional epoxy, polyphenylene ether, epoxy/polyphenylene oxide, bismaleimide triazine (BT), Thermount, cyanate ester, polyimide, and liquid crystal polymer. In addition, the first wiring 130 may include Cu, Ni, stainless steel, or beryllium copper (BeCu).

The external connection bumps 160 may be located below the first wiring structure 100. The external connection bumps 160 may be electrically connected to an external device such as, for example, a motherboard. The external connection bumps 160 may be electrically connected to the first wiring 130. The external connection bumps 160 may transmit electrical signals from the first semiconductor chip 300 and the second semiconductor chip 400 to the external device through the first wiring 130. The first wiring 130 may be electrically connected to the external device through the external connection bumps 160. The external connection bumps 160 may include at least one from among conductive materials such as, for example, solder, Sn, silver (Ag), Cu, and Al.

The first semiconductor chip 300 may be mounted on the upper surface of the first wiring structure 100. The first semiconductor chip 300 may be electrically connected to the first wiring 130. According to some embodiments, using a flip chip method, the first semiconductor chip 300 may be mounted on the first wiring structure 100 through chip connection bumps 350, such as micro bumps. According to some embodiments, an underfill material layer 360 that surrounds the chip connection bumps 350 may be placed between the first semiconductor chip 300 and the first wiring structure 100. The underfill material layer 360 may include, for example, epoxy resin formed by a capillary underfill method. However, in some embodiments, the molding member 390 may directly fill the gap between the first semiconductor chip 300 and the first wiring structure 100 through a molded underfill process. In this case, the underfill material layer 360 may be omitted.

The first semiconductor chip 300 may include a memory chip or a logic chip. The memory chip may include, for example, a volatile memory chip, such as dynamic random-access memory (DRAM) or static random-access memory (SRAM), or a non-volatile memory chip, such as phase-change random-access memory (PRAM), magnetoresistive random-access memory (MRAM), ferroelectric random-access memory (FeRAM), or resistive random-access memory (RRAM). The logic chip may include, for example, a microprocessor, such as a central processing unit (CPU), a graphics processing unit (GPU), or an application processor (AP), an analog device, or a digital signal processor.

The molding member 390 may be configured to surround the first semiconductor chip 300 and the conductive pillar 500 on the upper surface of the first wiring structure 100. In some embodiments, the molding member 390 may cover sides and an upper surface of the first semiconductor chip 300.

The molding member 390 may include thermosetting resin, such as epoxy resin, thermoplastic resin, such as polyimide, or resin including reinforcing materials, such as inorganic filler, specifically Ajinomoto build-up film (ABF), FR-4, BT, and the like, but is not limited thereto. The molding member 390 may include a molding material, such as epoxy mold compound (EMC), or a photosensitive material, such as photoimageable encapsulant (PIE). In some embodiments, a portion of the molding member 390 may include an insulating material, such as a silicon oxide film, a silicon nitride film, or a silicon oxynitride film.

The conductive pillar 500 may be spaced horizontally apart from the first semiconductor chip 300 on the upper surface of the first wiring structure 100. According to some embodiments, a plurality of conductive pillars 500 may be provided. The plurality of conductive pillars 500 may be spaced horizontally apart from each other at certain intervals. The conductive pillars 500 may extend in the vertical direction Z and may pass through the molding member 390 in the vertical direction Z.

The conductive pillars 500 may electrically connect the second wiring structure 200 to the first wiring structure 100. That is, the conductive pillar 500 may include a vertical connection conductor for electrically connecting the first wiring structure 100 to the second wiring structure 200.

According to some embodiments, the conductive pillar 500 may include a lower portion 500_DL, a middle portion 500_ML, and an upper portion 500_UL, as shown in FIG. 2.

According to some embodiments, the lower portion 500_DL, the middle portion 500_ML, and the upper portion 500_UL of the conductive pillar 500 may be distinguished by vertical levels thereof. The lower portion 500_DL of the conductive pillar 500 may refer to a portion of the conductive pillar 500 from the lower surface of the conductive pillar 500 to a first vertical level of the conductive pillar 500, wherein the first vertical level may be defined as the highest vertical level of a portion of the conductive pillar 500 where the cross-sectional area along the X-Y plane is substantially the same (e.g., constant). In the same sense, a portion of the conductive pillar 500 where the cross-sectional area along the X-Y plane is substantially the same (e.g., constant) may be understood as the lower portion 500_DL of the conductive pillar 500. In addition, in the same sense, a portion of the conductive pillar 500 where the cross-sectional area along the X-Y plane is substantially the same as the cross-sectional area of the lower surface of the conductive pillar 500 may be understood as the lower portion 500_DL of the conductive pillar 500.

The middle portion 500_ML of the conductive pillar 500 may refer to a portion of the conductive pillar 500 where the cross-sectional area along the X-Y plane increases. That is, the middle portion 500_ML may be a portion of the conductive pillar 500 from the lower portion 500_DL of the conductive pillar 500 to a second vertical level of the conductive pillar 500, wherein the second vertical level may be understood as the same vertical level as the upper surface of the molding member 390. In the same sense, a portion of the conductive pillar 500 where the cross-sectional area along the X-Y plane changes as the vertical level thereof increases may be understood as the middle portion 500_ML of the conductive pillar 500. In some embodiments, the cross-sectional area of the middle portion 500_ML of the conductive pillar 500 along the X-Y plane may increase as the vertical level thereof increases. In some embodiments, the cross-sectional area of the middle portion 500_ML of the conductive pillar 500 along the X-Y plane may also decrease as the vertical level thereof increases.

The upper portion 500_UL of the conductive pillar 500 may be defined as a portion of the conductive pillar 500 that has a vertical level equal to or greater than the upper surface of the molding member 390. As the vertical level of the upper portion 500_UL of the conductive pillar 500 increases, the cross-sectional area thereof along the X-Y plane may decrease.

The sides of the lower portion 500_DL of the conductive pillar 500 may have a shape of a straight line extending in the vertical direction Z, the sides of the middle portion 500_ML of the conductive pillar 500 may have a shape that becomes thicker or thinner in the horizontal direction X and/or Y as the vertical level thereof increases, and the upper portion 500_UL of the conductive pillar 500 may have a dome shape.

The cross-section of the lower portion 500_DL of the conductive pillar 500 along the X-Z plane may have a rectangular shape. The cross-section of the middle portion 500_ML of the conductive pillar 500 along the X-Z plane may have a trapezoidal shape. The cross-section of the upper portion 500_UL of the conductive pillar 500 along the X-Z plane may have an upwardly convex shape.

The lower portion 500_DL of the conductive pillar 500 may have a constant cross-sectional area along the X-Y plane regardless of the vertical level. As the vertical level of the middle portion 500_ML of the conductive pillar 500 increases, the cross-sectional area thereof along the X-Y plane may increase or decrease. In some embodiments, the middle portion 500_ML of the conductive pillar 500 may extend in the horizontal directions X and Y toward the molding member 390 as the vertical level thereof increases. Accordingly, at least part of the middle portion 500_ML of the conductive pillar 500 may not overlap with the lower portion 500_DL of the conductive pillar 500 in the vertical direction Z. The sides of the lower portion 500_DL of the conductive pillar 500 may have the same horizontal level. In some embodiments, the horizontal level of the sides of the middle portion 500_ML of the conductive pillar 500 may increase horizontally as the vertical level thereof increases. The sides of the middle portion 500_ML of the conductive pillar 500 may have a greater level in the horizontal direction X and/or Y than the sides of the lower portion 500_DL of the conductive pillar 500.

The vertical level of the upper portion 500_UL of the conductive pillar 500 may be the greatest at the center of the conductive pillar 500, in the horizontal direction X and/or Y, and may decrease away from the center. According to some embodiments, the upper portion 500_UL of the conductive pillar 500 may have an upwardly convex shape.

According to some embodiments, in the cross-section of the conductive pillar 500 along the X-Z plane, both sides of the middle portion 500_ML may extend diagonally upward. For example, with reference to FIG. 2, in the cross-section of the conductive pillar 500 along the X-Z plane, the right side of the middle portion 500_ML may have the shape of a straight line extending toward the upper right, and the left side of the middle portion 500_ML may have a shape of a straight line extending toward the upper left. However, the shape of the middle portion 500_ML of the conductive pillar 500 is not limited thereto. In some embodiments, the sides of the middle portion 500_ML of the conductive pillar 500 may have a curved shape.

The second wiring structure 200 may be disposed on the upper surface of the molding member 390. The second wiring structure 200 may include an upper surface and a lower surface that are opposite to each other, wherein at least one of the upper surface and the lower surface thereof may be flat. The second wiring structure 200 may electrically connect the conductive pillar 500 to the second semiconductor chip 400. The second wiring structure 200 may include second wiring 230 and a second wiring insulating layer 210. The second wiring structure 200 may electrically connect the conductive pillar 500 to the second semiconductor chip 400 through the second wiring 230. The second wiring insulating layer 210 may be provided as a plurality of insulating layers (e.g., a plurality of second wiring insulating layers 210) stacked in the vertical direction Z. The second wiring 230 may include a second wiring via 231 and a second wiring line 233.

Since the second wiring 230 and the second wiring insulating layer 210 may be substantially the same as or similar to the first wiring 130 and the first wiring insulating layer 110, described above, respectively, duplicate descriptions thereof may be omitted.

According to some embodiments, the footprint (e.g., a size in a plan view) of the second wiring via 231 in physical contact with the upper portion 500_UL of the conductive pillar 500 may be less than the footprint (e.g., a size in the plan view) of the upper portion 500_UL of the conductive pillar 500. According to some embodiments, one conductive pillar 500 may physically contact a plurality of second wiring vias 231.

The second semiconductor chip 400 may be mounted on the upper surface of the second wiring structure 200. The second semiconductor chip 400 may be mounted, using a flip chip method, on the upper surface of the second wiring structure 200 through chip connection bumps 450.

The second semiconductor chip 400 may include a memory chip or a logic chip. In some embodiments, the second semiconductor chip 400 may include a memory chip. According to some embodiment, the second semiconductor chip 400 may be mounted on the second wiring structure 200 while being sealed by a molding member. According to some embodiments, an underfill material layer 490 that surrounds the chip connection bumps 450 may be placed between the second semiconductor chip 400 and the second wiring structure 200. The underfill material layer 490 may include, for example, epoxy resin formed by a capillary underfill method. However, in some embodiments, a molding material may directly fill the gap between the second semiconductor chip 400 and the second wiring structure 200 through a molded underfill process. In this case, the underfill material layer 490 may be omitted.

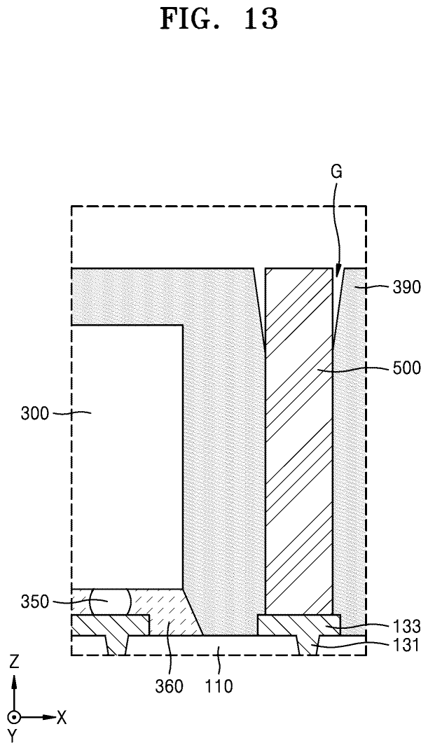

Previously, there may be a gap G (see FIG. 13) between the conductive pillar 500 and the molding member 390. The gap G may be formed for various reasons, such as the difference in thermal conductivity coefficient between the molding member 390 and the conductive pillar 500, external force, and surface oxidation of the conductive pillar 500. Therefore, it is difficult to completely prevent gaps from being formed.

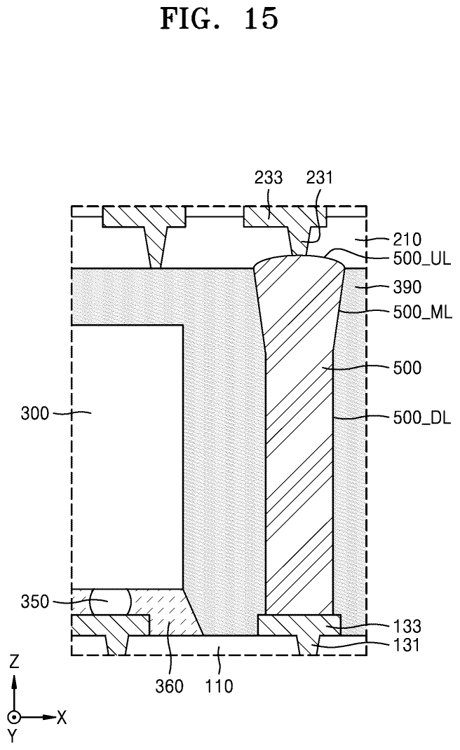

However, as described below with reference to FIGS. 13 and 15, in the semiconductor package 10 according to some embodiments of the present disclosure, when the gap G is formed between the conductive pillar 500 and the molding member 390, the gap G between the conductive pillar 500 and the molding member 390 may be filled by re-plating the gap G. Through the process, rather than the conventional shape extending in the vertical direction Z, the conductive pillar 500 may have a shape in which the cross-sectional area of the conductive pillar 500 along the X-Y plane changes in the middle portion 500_ML of the conductive pillar 500, and the upper portion 500_UL of the conductive pillar 500 has a greater vertical level than the upper surface of the molding member 390 and has a dome shape.

In the semiconductor package 10 according to some embodiments the present disclosure, when the gap G of the conductive pillar 500 is formed, the gap G may be filled through plating. Thus, the connection defects between the second wiring 230 and the conductive pillar 500 may be prevented and cracks within the semiconductor package 10 may be reduced, thereby improving the structural reliability of the semiconductor package 10.

In addition, in the semiconductor package 10 according to some embodiments the present disclosure, the shape of the conductive pillar 500 may be changed through plating to refill the gap G when the gap G is formed, rather than preventing the gap G between the conductive pillar 500 and the molding member 390. Thus, the gap G within semiconductor package 10 may be minimized.

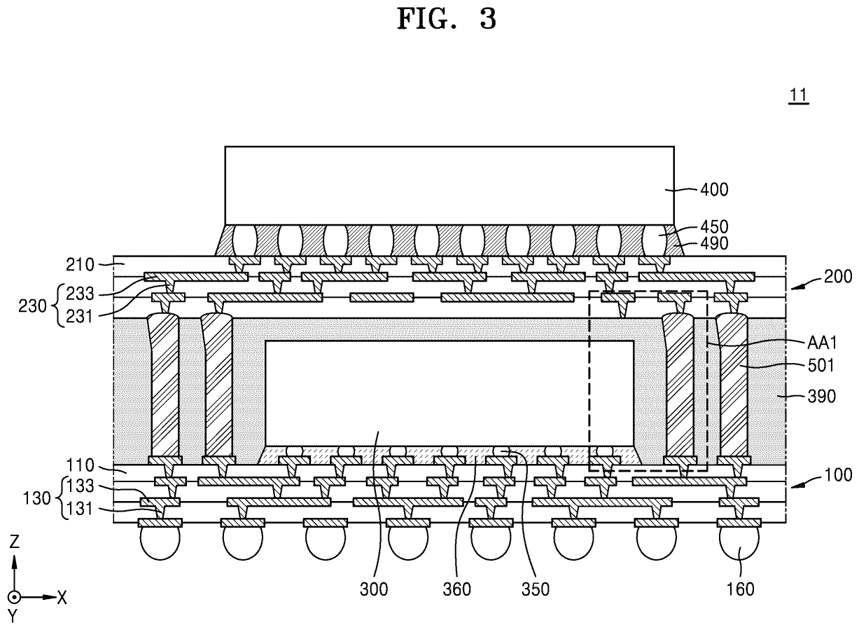

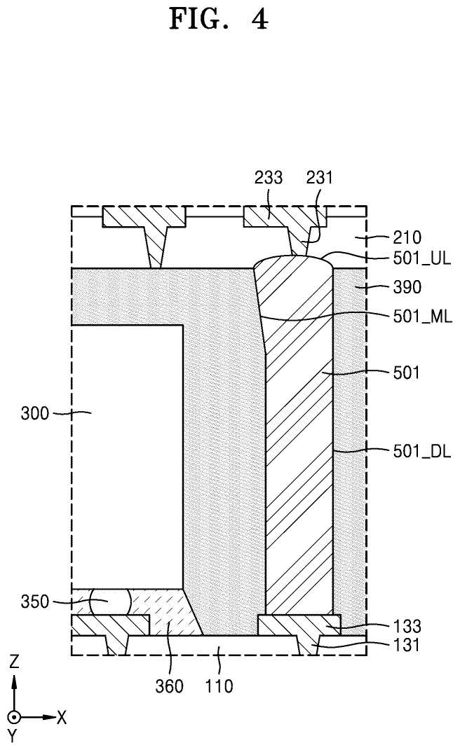

FIG. 3 is a cross-sectional view of a semiconductor package 11 according to an embodiment. FIG. 4 is an enlarged view of a portion AA1 in FIG. 3. Hereinafter, the description may focus on the differences between the semiconductor package 10 described with reference to FIGS. 1 and 2 and the semiconductor package 11 described with reference to FIGS. 3 and 4. Thus, repeated descriptions may be omitted.

Referring to FIGS. 3 and 4, the semiconductor package 11 according to some embodiments the present disclosure may include a first wiring structure 100, a first semiconductor chip 300, a second wiring structure 200, a conductive pillar 501, a molding member 390, and a second semiconductor chip 400.

The first wiring structure 100 may be placed below the first semiconductor chip 300 and may electrically connect the first semiconductor chip 300 to external connection bumps 160. The first wiring structure 100 may include a first wiring insulating layer 110 and first wiring 130. The first wiring 130 may include a first wiring via 131 and a first wiring line 133. The external connection bumps 160 may be located below the first wiring structure 100. The first semiconductor chip 300 may be mounted on the upper surface of the first wiring structure 100. The molding member 390 may be formed to surround the first semiconductor chip 300 and the conductive pillar 501 on the upper surface of the first wiring structure 100.

The conductive pillar 501 may be spaced horizontally apart from the first semiconductor chip 300 on the upper surface of the first wiring structure 100. According to some embodiments, a plurality of conductive pillars 501 may be provided. The plurality of conductive pillars 501 may be spaced horizontally apart from each other at certain intervals. The conductive pillars 501 may extend in the vertical direction Z and may pass through the molding member 390 in the vertical direction Z.

As shown in FIG. 4, the conductive pillar 501 may include a lower portion 501_DL, a middle portion 501_ML, and an upper portion 501_UL.

According to some embodiments, the lower portion 501_DL, the middle portion 501_ML, and the upper portion 501_UL of the conductive pillar 501 may be distinguished by vertical levels thereof. The lower portion 501_DL of the conductive pillar 501 may refer to a portion from the lower surface of the conductive pillar 501 to a first vertical level of the conductive pillar 501, wherein the first vertical level may be defined as the highest vertical level of a portion of the conductive pillar 501 where the cross-sectional area along the X-Y plane is substantially the same (e.g., constant).

The middle portion 501_ML of the conductive pillar 501 may refer to a portion of the conductive pillar 501 where the cross-sectional area along the X-Y plane increases. That is, the middle portion 501_ML may be a portion of the conductive pillar 501 from the lower portion 501_DL of the conductive pillar 501 to a second vertical level of the conductive pillar 501, wherein the second vertical level may be understood as the same vertical level as the upper surface of the molding member 390. In the same sense, a portion of the conductive pillar 501 where the cross-sectional area along the X-Y plane changes as the vertical level thereof increases may be understood as the middle portion 501_ML of the conductive pillar 501. In some embodiments, the cross-sectional area of the middle portion 501_ML of the conductive pillar 501 along the X-Y plane may increase as the vertical level thereof increases. In some embodiments, the cross-sectional area of the middle portion 501_ML of the conductive pillar 501 along the X-Y plane may also decrease as the vertical level thereof increases.

The upper portion 501_UL of the conductive pillar 501 may be defined as a portion of the conductive pillar 501 that has a vertical level equal to or greater than the upper surface of the molding member 390. As the vertical level of the upper portion 501_UL of the conductive pillar 501 increases, the cross-sectional area thereof along the X-Y plane may decrease.

The sides of the lower portion 501_DL of the conductive pillar 501 may extend in the vertical direction Z. At least part of the sides of the middle portion 501_ML of the conductive pillar 501 may have a shape that becomes thicker or thinner in the horizontal direction X and/or Y as the vertical level thereof increases, and at least part of the sides of the middle portion 501_ML of the conductive pillar 501 may extend upward in the vertical direction Z. The upper portion 501_UL of the conductive pillar 501 may have a dome shape.

The cross-section of the lower portion 501_DL of the conductive pillar 501 along the X-Z plane may have a rectangular shape. The cross-section of the middle portion 501_ML of the conductive pillar 501 along the X-Z plane may have a shape in which the right side extends upward in the vertical direction Z and the left side has a horizontal level that increases in the −X direction as the vertical level of the right side increases. In the same sense, in the cross-section of the middle portion 501_ML of the conductive pillar 501 along the X-Z plane, the right side may have a shape of a straight line extending upward in the vertical direction Z and the left side may have a shape of a diagonal line extending toward the upper left. The cross-section of the upper portion 501_UL of the conductive pillar 501 along the X-Z plane may have an upward convex shape.

In some embodiments, at least part of the middle portion 501_ML of the conductive pillar 501 may extend in the horizontal directions X and Y toward the molding member 390 as the vertical level thereof increases. Accordingly, at least part of the middle portion 501_ML of the conductive pillar 501 may not overlap with the lower portion 501_DL of the conductive pillar 501 in the vertical direction Z. The sides of the lower portion 501_DL of the conductive pillar 501 may have the same horizontal level. In some embodiments, in the conductive pillar 501, the horizontal level of at least part of the sides of the middle portion 501_ML may have a level that increases horizontally as the vertical level thereof increases. For example, in the conductive pillar 501, the horizontal level of the left side of the sides of the middle portion 501_ML may increase horizontally as the vertical level thereof increases. The sides of the middle portion 501_ML of the conductive pillar 501 may have a greater level in the horizontal direction X and/or Y than the sides of the lower portion 501_DL of the conductive pillar 501.

The vertical level of the upper portion 501_UL of the conductive pillar 501 may be the greatest at the center of the conductive pillar 501, in a horizontal direction X and/or Y, and may decrease away from the center. According to some embodiments, the upper portion 501_UL of the conductive pillar 501 may have an upwardly convex shape.

According to some embodiments, in the cross-section of the conductive pillar 501 along the X-Z plane, one side of the middle portion 501_ML may extend diagonally upward and the other side thereof may extend upward in the vertical direction Z. For example, with reference to FIG. 4, in the cross-section of the conductive pillar 501 along the X-Z plane, the left side of the middle portion 501_ML may have a shape of a straight line extending toward the upper left, and the right side of the middle portion 501_ML may have a shape of a straight line extending upward in the vertical direction Z. However, the shape of the middle portion 501_ML of the conductive pillar 501 is not limited thereto. In some embodiments, the left side of the middle portion 501_ML of the conductive pillar 501 may have a curved shape.

The second wiring structure 200 may be disposed on the upper surface of the molding member 390. The second wiring structure 200 may include second wiring 230 and a second wiring insulating layer 210. The second wiring 230 may include a second wiring via 231 and a second wiring line 233.

According to some embodiments, the footprint of the second wiring via 231 in physical contact with the upper portion 501_UL of the conductive pillar 501 may be less than the footprint of the upper portion 501_UL of the conductive pillar 501. According to some embodiments, one conductive pillar 501 may physically contact a plurality of second wiring vias 231.

The second semiconductor chip 400 may be mounted on the upper surface of the second wiring structure 200. The second semiconductor chip 400 may be mounted, using a flip chip method, on the upper surface of the second wiring structure 200 through chip connection bumps 450.

In the semiconductor package 11 according to some embodiments the present disclosure, the conductive pillar 501 may include the lower portion 501_DL, the middle portion 501_ML, and the upper portion 501_UL while filling the gap G (see FIG. 13) between the left side of the conductive pillar 501 and the molding member 390 through plating. As a result, the gap G between the conductive pillar 501 and the molding member 390 within the semiconductor package 11 may be reduced, thereby minimizing connection defects in the semiconductor package 11 and improving structural stability.

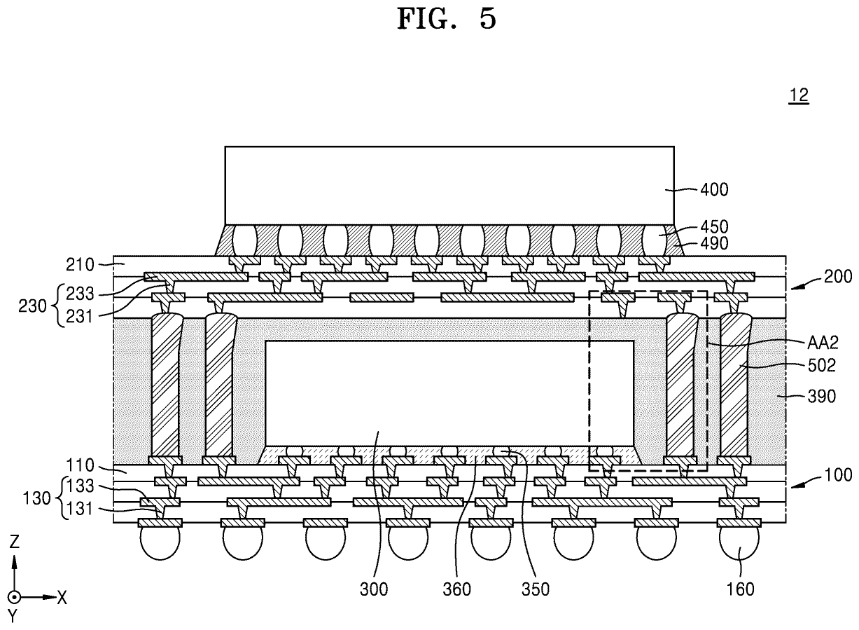

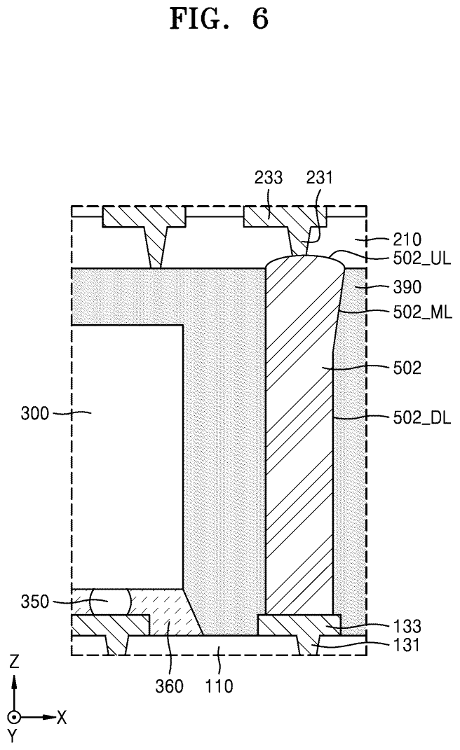

FIG. 5 is a cross-sectional view of a semiconductor package according to an embodiment. FIG. 6 is an enlarged view of a portion AA2 in FIG. 5. Hereinafter, the description may focus on the differences between the semiconductor package 11 described with reference to FIGS. 3 and 4 and a semiconductor package 12 described with reference to FIGS. 5 and 6. Thus, repeated descriptions may be omitted.

Referring to FIGS. 5 and 6, the semiconductor package 12 according to some embodiments the present disclosure may include a first wiring structure 100, a first semiconductor chip 300, a second wiring structure 200, a conductive pillar 502, a molding member 390, and a second semiconductor chip 400.

The first wiring structure 100 may be placed below the first semiconductor chip 300 and may electrically connect the first semiconductor chip 300 to external connection bumps 160. The first wiring structure 100 may include a first wiring insulating layer 110 and first wiring 130. The first wiring 130 may include a first wiring via 131 and a first wiring line 133. The external connection bumps 160 may be located below the first wiring structure 100. The first semiconductor chip 300 may be mounted on the upper surface of the first wiring structure 100. The molding member 390 may be formed to surround the first semiconductor chip 300 and the conductive pillar 502 on the upper surface of the first wiring structure 100.

The conductive pillar 502 may be spaced horizontally apart from the first semiconductor chip 300 on the upper surface of the first wiring structure 100. According to some embodiments, a plurality of conductive pillars 502 may be provided. The plurality of conductive pillars 502 may be spaced horizontally apart from each other at certain intervals. The conductive pillars 502 may extend in the vertical direction Z and may pass through the molding member 390 in the vertical direction Z.

As shown in FIG. 6, the conductive pillar 502 may include a lower portion 502_DL, a middle portion 502_ML, and an upper portion 502_UL.

According to some embodiments, the lower portion 502_DL, the middle portion 502_ML, and the upper portion 502_UL of the conductive pillar 502 may be distinguished by vertical levels thereof. The lower portion 502_DL of the conductive pillar 502 may refer to a portion from the lower surface of the conductive pillar 502 to a first vertical level of the conductive pillar 502, wherein the first vertical level may be defined as the highest vertical level of a portion of the conductive pillar 502 where the cross-sectional area along the X-Y plane is substantially the same (e.g., constant).

The middle portion 502_ML of the conductive pillar 502 may refer to a portion of the conductive pillar 502 where the cross-sectional area along the X-Y plane increases. That is, the middle portion 502_ML may be a portion of the conductive pillar 502 from the lower portion 502_DL of the conductive pillar 502 to a second vertical level of the conductive pillar 502, wherein the second vertical level may be understood as the same vertical level as the upper surface of the molding member 390. In the same sense, a portion of the conductive pillar 502 where the cross-sectional area along the X-Y plane changes as the vertical level thereof increases may be understood as the middle portion 502_ML of the conductive pillar 502. In some embodiments, the cross-sectional area of the middle portion 502_ML of the conductive pillar 502 along the X-Y plane may increase as the vertical level thereof increases. In some embodiments, the cross-sectional area of the middle portion 502_ML of the conductive pillar 502 along the X-Y plane may also decrease as the vertical level thereof increases.

The upper portion 502_UL of the conductive pillar 502 may be defined as a portion of the conductive pillar 502 that has a vertical level equal to or greater than the upper surface of the molding member 390. As the vertical level of the upper portion 502_UL of the conductive pillar 502 increases, the cross-sectional area thereof along the X-Y plane may decrease.

The sides of the lower portion 502_DL of the conductive pillar 502 may extend in the vertical direction Z. At least part of the sides of the middle portion 502_ML of the conductive pillar 502 may have a shape that becomes thicker or thinner in the horizontal direction X and/or Y as the vertical level thereof increases, and at least part of the sides of the middle portion 502_ML of the conductive pillar 502 may extend upward in the vertical direction Z. The upper portion 502_UL of the conductive pillar 502 may have a dome shape.

The cross-section of the lower portion 502_DL of the conductive pillar 502 along the X-Z plane may have a rectangular shape. The cross-section of the middle portion 502_ML of the conductive pillar 502 along the X-Z plane may have a shape in which the left side extends upward in the vertical direction Z and the right side has a horizontal level that increases in the +X direction as the vertical level of the left side increases. In the same sense, in the cross-section of the middle portion 502_ML of the conductive pillar 502 along the X-Z plane, the left side may have a shape of a straight line extending upward in the vertical direction Z, and the right side may have a shape of a diagonal line extending toward the upper right. The cross-section of the upper portion 502_UL of the conductive pillar 502 along the X-Z plane may have an upward convex shape.

In some embodiments, at least part of the middle portion 502_ML of the conductive pillar 502 may extend in the horizontal directions X and Y toward the molding member 390 as the vertical level thereof increases. Accordingly, at least part of the middle portion 502_ML of the conductive pillar 502 may not overlap with the lower portion 502_DL of the conductive pillar 502 in the vertical direction Z. The sides of the lower portion 502_DL of the conductive pillar 502 may have the same horizontal level. In some embodiments, in the conductive pillar 502, the horizontal level of at least part of the sides of the middle portion 502_ML may have a level that increases horizontally as the vertical level thereof increases. For example, in the conductive pillar 502, the horizontal level of the right side of the sides of the middle portion 502_ML may increase horizontally as the vertical level thereof increases. The sides of the middle portion 502_ML of the conductive pillar 502 may have a greater level in the horizontal direction X and/or Y than the sides of the lower portion 502_DL of the conductive pillar 502.

The vertical level of the upper portion 502_UL of the conductive pillar 502 may be the greatest at the center of the conductive pillar 502, in a horizontal direction X and/or Y, and may decrease away from the center. According to some embodiments, the upper portion 502_UL of the conductive pillar 502 may have an upwardly convex shape.

According to some embodiments, in the cross-section of the conductive pillar 502 along the X-Z plane, one side of the middle portion 502_ML may extend diagonally upward, and the other side thereof may extend upward in the vertical direction Z. For example, with reference to FIG. 6, in the cross-section of the conductive pillar 502 along the X-Z plane, the right side of the middle portion 502_ML may have a shape of a straight line extending toward the upper right, and the left side of the middle portion 502_ML may have a shape of a straight line extending upward in the vertical direction Z. However, the shape of the middle portion 502_ML of the conductive pillar 502 is not limited thereto. In some embodiments, the right side of the middle portion 502_ML of the conductive pillar 502 may have a curved shape.

The second wiring structure 200 may be disposed on the upper surface of the molding member 390. The second wiring structure 200 may include second wiring 230 and a second wiring insulating layer 210. The second wiring 230 may include a second wiring via 231 and a second wiring line 233.

According to some embodiments, the footprint of the second wiring via 231 in physical contact with the upper portion 502_UL of the conductive pillar 502 may be less than the footprint of the upper portion 502_UL of the conductive pillar 502. According to some embodiments, one conductive pillar 502 may physically contact a plurality of second wiring vias 231.

The second semiconductor chip 400 may be mounted on the upper surface of the second wiring structure 200. The second semiconductor chip 400 may be mounted, using a flip chip method, on the upper surface of the second wiring structure 200 through chip connection bumps 450.

In the semiconductor package 12 according to some embodiments the present disclosure, the conductive pillar 502 may include the lower portion 502_DL, the middle portion 502_ML, and the upper portion 502_UL while filling the gap G (see FIG. 13) between the right side of the conductive pillar 502 and the molding member 390 through plating. As a result, the gap G between the conductive pillar 502 and the molding member 390 within the semiconductor package 12 may be reduced, thereby minimizing connection defects in the semiconductor package 12 and improving structural stability.

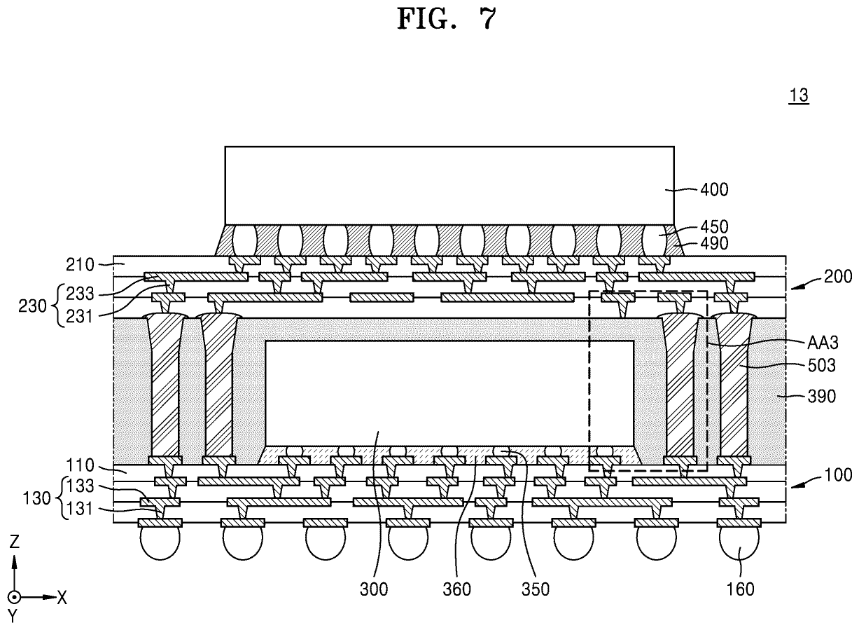

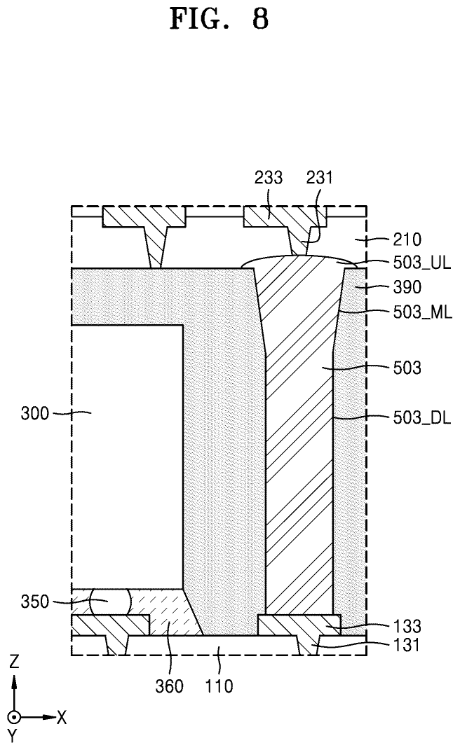

FIG. 7 is a cross-sectional view of a semiconductor package according to an embodiment. FIG. 8 is an enlarged view of a portion AA3 in FIG. 7. Hereinafter, the description may focus on the differences between the semiconductor packages 10, 11, and 12 described with reference to FIGS. 1 to 6 and a semiconductor package 13 described with reference to FIGS. 7 and 8. Thus, repeated descriptions may be omitted.

Referring to FIGS. 7 and 8, the semiconductor package 13, according to some embodiments the present disclosure, may include a first wiring structure 100, a first semiconductor chip 300, a second wiring structure 200, a conductive pillar 503, a molding member 390, and a second semiconductor chip 400.

The first wiring structure 100 may be placed below the first semiconductor chip 300 and may electrically connect the first semiconductor chip 300 to external connection bumps 160. The first wiring structure 100 may include a first wiring insulating layer 110 and first wiring 130. The first wiring 130 may include a first wiring via 131 and a first wiring line 133. The external connection bumps 160 may be located below the first wiring structure 100. The first semiconductor chip 300 may be mounted on the upper surface of the first wiring structure 100. The molding member 390 may be formed to surround the first semiconductor chip 300 and the conductive pillar 503 on the upper surface of the first wiring structure 100.

The conductive pillar 503 may be spaced horizontally apart from the first semiconductor chip 300 on the upper surface of the first wiring structure 100. According to some embodiments, a plurality of conductive pillars 503 may be provided. The plurality of conductive pillars 503 may be spaced horizontally apart from each other at certain intervals. The conductive pillars 503 may extend in the vertical direction Z and may pass through the molding member 390 in the vertical direction Z.

As shown in FIG. 8, the conductive pillar 503 may include a lower portion 503_DL, a middle portion 503_ML, and an upper portion 503_UL.

According to some embodiments, the lower portion 503_DL, the middle portion 503_ML, and the upper portion 503_UL of the conductive pillar 503 may be distinguished by vertical levels thereof. The lower portion 503_DL of the conductive pillar 503 may refer to a portion from the lower surface of the conductive pillar 503 to a first vertical level of the conductive pillar 503, wherein the first vertical level may be defined as the highest vertical level of a portion of the conductive pillar 503 where the cross-sectional area along the X-Y plane is substantially the same (e.g., constant).

The middle portion 503_ML of the conductive pillar 503 may refer to a portion of the conductive pillar 503 where the cross-sectional area along the X-Y plane increases. That is, the middle portion 503_ML may be a portion of the conductive pillar 503 from the lower portion 503_DL of the conductive pillar 503 to a second vertical level of the conductive pillar 503, wherein the second vertical level may be understood as the same vertical level as the upper surface of the molding member 390. In the same sense, a portion of the conductive pillar 503 where the cross-sectional area along the X-Y plane changes as the vertical level thereof increases may be understood as the middle portion 503_ML of the conductive pillar 503. In some embodiments, the cross-sectional area of the middle portion 503_ML of the conductive pillar 503 along the X-Y plane may increase as the vertical level thereof increases. In some embodiments, the cross-sectional area of the middle portion 503_ML of the conductive pillar 503 along the X-Y plane may also decrease as the vertical level thereof increases.

The upper portion 503_UL of the conductive pillar 503 may be defined as a portion of the conductive pillar 503 that has a vertical level equal to or greater than the upper surface of the molding member 390. As the vertical level of the upper portion 503_UL of the conductive pillar 503 increases, the cross-sectional area thereof along the X-Y plane may decrease.

The sides of the lower portion 503_DL of the conductive pillar 503 may have a shape of a straight line extending in the vertical direction Z. In some embodiments, at least part of the sides of the middle portion 503_ML of the conductive pillar 503 may have a shape that becomes thicker or thinner in the horizontal direction X and/or Y as the vertical level thereof increases. In addition, in some embodiments, all of the sides of the middle portion 503_ML of the conductive pillar 503 may have a shape that becomes thicker or thinner in the horizontal direction X and/or Y as the vertical level thereof increases. The upper portion 503_UL of the conductive pillar 503 may have a dome shape.

The cross-section of the lower portion 503_DL of the conductive pillar 503 along the X-Z plane may have a rectangular shape. The cross-section of the middle portion 503_ML of the conductive pillar 503 along the X-Z plane may have a trapezoidal shape. The cross-section of the upper portion 503_UL of the conductive pillar 503 along the X-Z plane may have an upwardly convex shape.

The vertical level of the upper portion 503_UL of the conductive pillar 503 may be the greatest at a center of the conductive pillar 502, in a horizontal direction X and/or Y, and may decrease away from the center. According to some embodiments, the upper portion 503_UL of the conductive pillar 503 may have an upwardly convex shape.

A part of the upper portion 503_UL of the conductive pillar 503 may contact the upper surface of the molding member 390. According to some embodiments, the cross-sectional area of a part of the upper portion 503_UL of the conductive pillar 503 located at the lowest level of the upper portion 503_UL along the X-Y plane may be greater than the cross-sectional area of a part of the middle portion 503_ML of the conductive pillar 503 located at the highest level of the middle portion 503_ML along the X-Y plane. At least part of the upper portion 503_UL of the conductive pillar 503 may overlap with the molding member 390 in the vertical direction Z.

The second wiring structure 200 may be disposed on the upper surface of the molding member 390. The second wiring structure 200 may include second wiring 230 and a second wiring insulating layer 210. The second wiring 230 may include a second wiring via 231 and a second wiring line 233.

According to some embodiments, the footprint of the second wiring via 231 in physical contact with the upper portion 503_UL of the conductive pillar 503 may be less than the footprint of the upper portion 503_UL of the conductive pillar 503. According to some embodiments, one conductive pillar 503 may physically contact a plurality of second wiring vias 231.

The second semiconductor chip 400 may be mounted on the upper surface of the second wiring structure 200. The second semiconductor chip 400 may be mounted, using a flip chip method, on the upper surface of the second wiring structure 200 through chip connection bumps 450.

In the semiconductor package 13 according to some embodiments the present disclosure, the conductive pillar 503 may include the lower portion 503_DL, the middle portion 503_ML, and the upper portion 503_UL while filling the gap G (see FIG. 13) between the conductive pillar 503 and the molding member 390 through plating. As the upper portion 503_UL of the conductive pillar 503 is plated, a portion of the upper surface of the molding member 390 may also be plated. Accordingly, at least part of the upper portion 503_UL of the conductive pillar 503 may contact the upper surface of molding member 390. In the semiconductor package 13, the gap G between the conductive pillar 503 and the molding member 390 may be filled and a portion of the upper surface of the molding member 390 may be covered by the conductive pillar 503, thereby minimizing connection defects between the conductive pillar 503 and the second wiring via 231 in the semiconductor package 13 and improving structural stability.

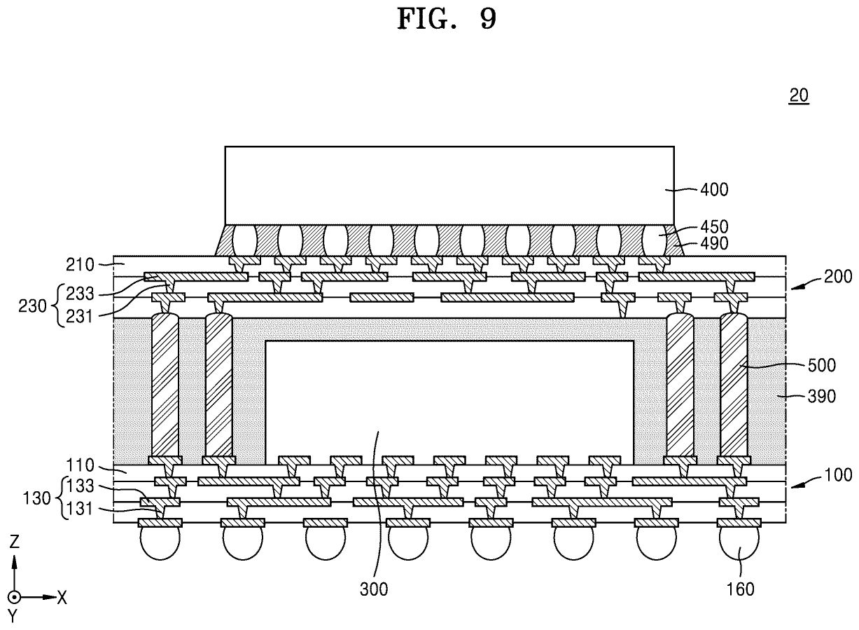

FIG. 9 is a cross-sectional view of a semiconductor package according to an embodiment. Hereinafter, repeated descriptions that are substantially the same as those given above with reference to FIGS. 1 to 8 may be omitted and differences are mainly described.

Referring to FIG. 9, a semiconductor package 20, according to some embodiments the present disclosure, may include a first wiring structure 100, a first semiconductor chip 300, a second wiring structure 200, a conductive pillar 500, a molding member 390, and a second semiconductor chip 400.

The first wiring structure 100 may be placed below the first semiconductor chip 300 and may electrically connect the first semiconductor chip 300 to the external connection bumps 160. The first wiring structure 100 may include a first wiring insulating layer 110 and first wiring 130. The first wiring 130 may include a first wiring via 131 and a first wiring line 133. The external connection bumps 160 may be located below the first wiring structure 100. The first semiconductor chip 300 may be mounted on the upper surface of the first wiring structure 100. Unlike FIG. 1, the first semiconductor chip 300 may be directly connected to the first wiring 130 without chip connection bumps 350 (see FIG. 1). These features may be shown when the first semiconductor chip 300 is formed by a chip-first process. The molding member 390 may be formed to surround the first semiconductor chip 300 and the conductive pillar 500 on the upper surface of the first wiring structure 100.

The conductive pillar 500 may be spaced horizontally apart from the first semiconductor chip 300 on the upper surface of the first wiring structure 100. According to some embodiments, a plurality of conductive pillars 500 may be provided. The plurality of conductive pillars 500 may be spaced horizontally apart from each other at certain intervals. The conductive pillars 500 may extend in the vertical direction Z and may pass through the molding member 390 in the vertical direction Z.

The conductive pillars 500 may include all embodiments of conductive pillars described with reference to FIGS. 1 to 8. Since the conductive pillars 500 may be substantially the same as those described with reference to FIGS. 1 to 8, repeated description thereof may be omitted.

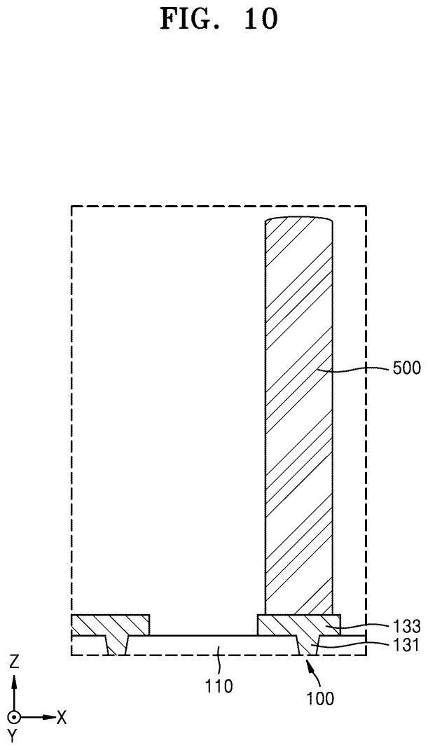

FIGS. 10 to 15 are cross-sectional views illustrating a method of manufacturing a semiconductor package according to some embodiments of the present disclosure. Hereinafter, repeated descriptions that are substantially the same as those given above with reference to FIGS. 1 to 8 may be omitted and differences are mainly described.

First, referring to FIG. 10, a first wiring structure 100 including a first wiring via 131 and a first wiring line 133, and a conductive pillar 500 in physical contact with the first wiring line 133 on the first wiring structure 100, are provided. A plurality of conductive pillars 500 may be provided on the first wiring structure 100. The upper surface of the conductive pillar 500 may have a dome shape. The dome shape may be formed during the plating process for forming the conductive pillar 500 in which the upper surface of the conductive pillar 500 protrudes vertically toward the center thereof in a horizontal direction X and/or Y.

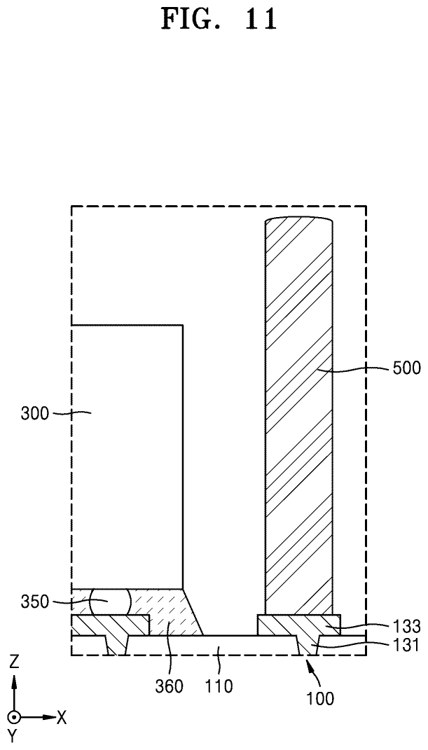

Refer to FIG. 11, the first semiconductor chip 300 is mounted on the first wiring structure 100. In some embodiments, using a flip chip method, the first semiconductor chip 300 may be mounted on the first wiring structure 100 through chip connection bumps 350. Additionally, in some embodiments, as described with reference to FIG. 9, the first semiconductor chip 300 may be mounted on the first wiring structure 100 without the chip connection bumps 350.

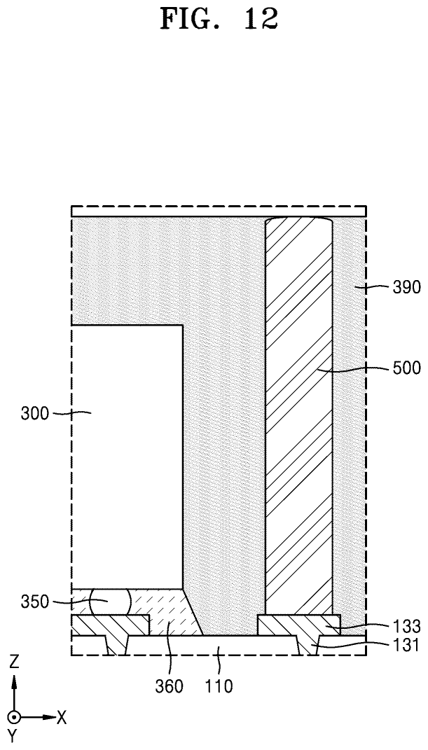

Referring to FIG. 12, a molding member 390 covering the first semiconductor chip 300 and the conductive pillar 500 is formed. The molding member 390 may cover the upper surface of the conductive pillar 500. In some embodiments, the vertical level of the upper surface of the molding member 390 may be greater than the vertical level of the upper surface of the conductive pillar 500.

Referring to FIG. 13, the molding member 390 and the conductive pillar 500 are etched. The etching may be performed through various processes, such as chemical mechanical polishing (CMP). Accordingly, the vertical level of the upper surface of the conductive pillar 500 may be the same as the vertical level of the upper surface of the molding member 390. Afterwards, the molding member 390 is cured. After the curing of the molding member 390 is completed, the gap G may be formed between the molding member 390 and the conductive pillar 500. The gap G may be formed for various reasons, such as the difference in thermal conductivity coefficient between the molding member 390 and the conductive pillar 500, external force, and surface oxidation of the conductive pillar 500.

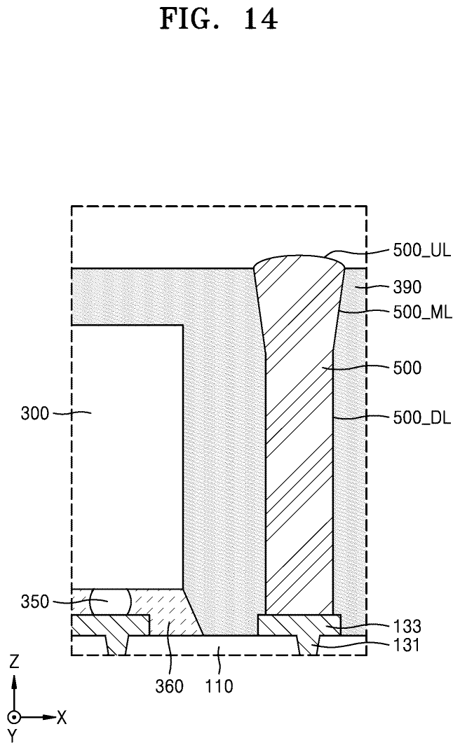

Referring to FIG. 14, the gap G (see FIG. 13) may be filled through a plating process. The plating process may be performed, for example, by electroless plating. The electroless plating may generally be performed by a person skilled in the art, and detailed description thereof may be omitted.

As the gap G is filled by the plating process, the conductive pillar 500 may include a lower portion 500_DL, a middle portion 500_ML, and an upper portion 500_UL. A part of the middle portion 500_ML of the conductive pillar 500 that does not overlap with the lower portion 500_DL of the conductive pillar 500 in the vertical direction Z may be formed by electroless plating. Additionally, an entirety of the upper portion 500_UL of the conductive pillar 500 may be formed by electroless plating. Since the lower portion 500_DL, the middle portion 500_ML, and the upper portion 500_UL of the conductive pillar 500 may be substantially the same as those described above with reference to FIGS. 1 to 8, repeated description thereof may be omitted.

Referring to FIG. 15, a second wiring via 231 physically connected to the upper portion 500_UL of the conductive pillar 500, a second wiring line 233 connected to the second wiring via 231 and extending horizontally, and a second wiring insulating layer 210 are formed. The footprint of the second wiring via 231 may be less than the footprint of the upper portion 500_UL of the conductive pillar 500. Additionally, the upper portion 500_UL of one conductive pillar 500 may be physically connected to a plurality of second wiring vias 231. The upper portion 500_UL of the conductive pillar 500 may physically contact each of the second wiring via 231 and the second wiring insulating layer 210.

While non-limiting example embodiments of the present disclosure have been particularly shown and described with reference to the drawings, it will be understood that various changes in form and details may be made therein without departing from the spirit and scope of the present disclosure.

What is claimed is:

1. A semiconductor package, comprising:
a first wiring structure comprising a first wiring and a first wiring insulating layer surrounding the first wiring;
a first semiconductor chip on the first wiring structure;
a conductive pillar on the first wiring structure and spaced apart from the first semiconductor chip in a horizontal direction;
a molding member covering the first semiconductor chip and the conductive pillar; and
a second wiring structure on the molding member, wherein the second wiring structure comprises a second wiring and a second wiring insulating layer surrounding the second wiring,
wherein the conductive pillar comprises a lower portion, a middle portion, and an upper portion, and
wherein the upper portion of the conductive pillar comprises a dome shape.

2. The semiconductor package of claim 1, wherein the lower portion of the conductive pillar is a first portion of the conductive pillar that has a cross-sectional area along a horizontal plane that is equal to a cross-sectional area of a lower surface of the conductive pillar along the horizontal plane,
wherein the middle portion of the conductive pillar is a second portion of the conductive pillar that has a cross-sectional area along the horizontal plane that increases as a vertical level of the middle portion increases, and
wherein the upper portion of the conductive pillar is a third portion of the conductive pillar that has a vertical level that is greater than a vertical level of an upper surface of the molding member.

3. The semiconductor package of claim 1, wherein at least one side of the middle portion of the conductive pillar extends upward in a completely vertical direction and at least another side of the middle portion of the conductive pillar extends in a diagonal direction.

4. The semiconductor package of claim 1, wherein two opposite sides of a cross-section of the middle portion of the conductive pillar along a vertical plane extend toward the molding member.

5. The semiconductor package of claim 1, wherein at least part of the upper portion of the conductive pillar overlaps with the molding member in a vertical direction.

6. The semiconductor package of claim 1, wherein at least part of the middle portion of the conductive pillar does not overlap with the lower portion of the conductive pillar in a vertical direction.

7. The semiconductor package of claim 1, wherein the upper portion of the conductive pillar is in contact with the second wiring, and the conductive pillar is in contact with a plurality of wiring vias.

8. The semiconductor package of claim 7, wherein, in a plan view, a size of each of the plurality of wiring vias is less than a size of the upper portion of the conductive pillar.

9. The semiconductor package of claim 1, wherein a part of the middle portion of the conductive pillar does not overlap with the lower portion of the conductive pillar in a vertical direction, and
wherein the part of the middle portion and the upper portion of the conductive pillar are formed by electroless plating.

10. The semiconductor package of claim 1, further comprising chip connection bumps between the first semiconductor chip and the first wiring structure.

11. The semiconductor package of claim 1, wherein chip connection bumps are not between the first semiconductor chip and the first wiring structure.

12. A semiconductor package, comprising:
a first wiring structure comprising a first wiring and a first wiring insulating layer surrounding the first wiring;
a first semiconductor chip on the first wiring structure;
a conductive pillar on the first wiring structure and spaced apart from the first semiconductor chip in a horizontal direction;
a molding member covering the first semiconductor chip and the conductive pillar; and
a second wiring structure on the molding member, wherein the second wiring structure comprises a second wiring and a second wiring insulating layer surrounding the second wiring,
wherein the second wiring comprises a wiring line and a plurality of wiring vias,
wherein the conductive pillar comprises a lower portion, a middle portion, and an upper portion,
wherein the lower portion of the conductive pillar is a first portion of the conductive pillar that has a cross-sectional area along a horizontal plane that is equal to a cross-sectional area of a lower surface of the conductive pillar along the horizontal plane,
wherein the middle portion of the conductive pillar is a second portion of the conductive pillar that has a cross-sectional area along the horizontal plane that increases as a vertical level of the middle portion increases,
wherein the upper portion of the conductive pillar is a third portion of the conductive pillar that has a vertical level that is greater than a vertical level of an upper surface of the molding member,
wherein the upper portion of the conductive pillar comprises a dome shape, and
wherein the upper portion of the conductive pillar is in contact with the plurality of wiring vias.

13. The semiconductor package of claim 12, wherein, in a plan view, a size of each of the plurality of wiring vias is less than a size of the upper portion of the conductive pillar.

14. The semiconductor package of claim 12, wherein a part of the middle portion of the conductive pillar does not overlap with the lower portion of the conductive pillar in a vertical direction, and
wherein the part of the middle portion and the upper portion of the conductive pillar are formed by electroless plating.

15. The semiconductor package of claim 12, wherein at least a part of the upper portion of the conductive pillar overlaps with the molding member in a vertical direction.

16. The semiconductor package of claim 12, wherein two opposite sides of a cross-section of the middle portion of the conductive pillar along a vertical plane extend toward the molding member.

17. The semiconductor package of claim 16, wherein a left side of the cross-section of the middle portion of the conductive pillar along the vertical plane has a shape of a diagonal line extending in an upper left direction and a right side of the cross-section of the middle portion of the conductive pillar along the vertical plane has a diagonal shape extending in an upper right direction.

18. A semiconductor package, comprising:
a first wiring structure comprising a first wiring and a first wiring insulating layer surrounding the first wiring;
a first semiconductor chip on the first wiring structure and connected to the first wiring structure by chip connection bumps;
an underfill material layer between the first semiconductor chip and the first wiring structure and surrounding the chip connection bumps;
a conductive pillar on the first wiring structure and spaced apart from the first semiconductor chip in a horizontal direction;
a molding member covering the first semiconductor chip and the conductive pillar;
a second wiring structure on the molding member, wherein the second wiring structure comprises second wiring and a second wiring insulating layer surrounding the second wiring, wherein the second wiring comprises a wiring line and a plurality of wiring vias; and
a second semiconductor chip on the second wiring structure;
wherein the conductive pillar comprises a lower portion, a middle portion, and an upper portion,
wherein the lower portion of the conductive pillar is a first portion of the conductive pillar that has a cross-sectional area along a horizontal plane that is equal to a cross-sectional area of a lower surface of the conductive pillar along the horizontal plane,
wherein the middle portion of the conductive pillar is a second portion of the conductive pillar that has a cross-sectional area along the horizontal plane that increases as a vertical level of the middle portion increases, and at least a part of the middle portion of the conductive pillar does not overlap with the lower portion of the conductive pillar in a vertical direction,
wherein the upper portion of the conductive pillar is a third portion of the conductive pillar that has a vertical level that is greater than a vertical level of an upper surface of the molding member,
wherein the upper portion of the conductive pillar comprises a dome shape,
wherein the upper portion of the conductive pillar is in contact with the plurality of wiring vias, and
wherein the part of the middle portion of the conductive pillar, that does not overlap with the lower portion of the conductive pillar in the vertical direction, and the upper portion of the conductive pillar are formed through electroless plating.

19. The semiconductor package of claim 18, wherein at least a part of the upper portion of the conductive pillar overlaps with the molding member in the vertical direction.

20. The semiconductor package of claim 18, wherein two opposite sides of a cross-section of the middle portion of the conductive pillar along a vertical plane extend toward the molding member.
